(19) United States
(12) Patent Application Publication
(10) Pub. No.: US 2006/0226545 A1
(43) Pub. Date: Oct. 12, 2006

(54) Semiconductor device

(75) Inventors: Shinji Suminoe, Tenri-shi (JP); Hiroyuki Nakanishi, Soraku-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/384,549

(22) Filed: Mar. 21, 2006

(30) Foreign Application Priority Data
Apr. 6, 2005 (JP) 2005-110258

(51) Int. Cl. H01L 23/48

(52) U.S. Cl. 257/738

(57) ABSTRACT

A semiconductor device includes: a semiconductor substrate having a semiconductor element; an electrode pad electrically connected to the semiconductor element; an insulating layer formed on the substrate, the insulating layer having an opening extended to the electrode pad; a wiring portion electrically connected to the electrode pad via the opening, the wiring portion having an edge located on the insulating layer; and a conductive bump formed directly above the electrode pad so as to cover upper and side surfaces of the wiring portion.

### CROSS-REFERENCE TO RELATED APPLICATION

This application is related to Japanese Patent Application No. 2005-110258 filed on Apr. 6, 2005, whose priory is claimed and the disclosure of which is incorporated by reference in its entirety.

### BACKGROUND OF THE INVENTION

1. Field of the Invention

The present invention relates to a semiconductor device, which is, in particular, suitably applicable to a chip scale package (CSP).

2. Description of Related Art

A trend for smaller, lighter and more functional electronic apparatuses such as cellular phones and the like has increased a demand for reduction in size and weight of IC chip packages. In order to meet such a demand, wafer-level CSPs, which are packages of a size equal to a chip size, have become widely used. The wafer-level CSPs allow for lower packaging cost because a large number of chips can be collectively packaged at wafer-level, and thus, a large number of IC chips can be packaged at a time in a miniature IC.

FIG. 4 (a cross-sectional view) shows a typical structure of the wafer-level CSPs. In the structure, there are formed, on a semiconductor substrate 53 having an electrode pad 51 formed thereon, an inorganic insulting layer 55 and a first organic insulating layer 57 each having an opening extended to the electrode pad 51. On the first organic insulating layer 57, a wiring layer 59 (composed of a barrier layer 59a and a main conductor layer 59b) which is electrically connected to the electrode pad 51 is formed, and a second organic insulating layer 61 for protecting the wiring layer is formed. The second organic insulating layer 61 has an opening formed in a portion where an external output terminal is to be formed, and an external output terminal 63 made of a solder is formed on the wiring layer 59 via the opening.

An area where external output terminals can be formed is limited in the wafer-level CSPs. Therefore, when there exist a large number of external output terminals, the external output terminal 63 need to be disposed directly above the electrode pad 51, in some cases. In such a case, there are problems that the electrode pad 51 below the external output terminal 63 tends to be affected by stress generated during and after mounting, which may cause cracking of the substrate 53 and destroy wirings or elements inside the substrate 53, whereby defects may occur.

Japanese Unexamined Patent Publication No. HEI 10(1998)-173006 discloses a semiconductor device shown in FIG. 5 (a cross-sectional view) having a structure with a modified external output terminal in view of effects caused by stress. The semiconductor device includes a semiconductor substrate 73 having an electrode pad 71 formed thereon, an inorganic insulating layer 75 having an opening extended to the pad 71 formed on the substrate 73, and an external output terminal 77 formed of a conductive resin ball mounted on the pad 71 via a conductive material 79. The conductive resin ball is composed of a resin ball 77a of a heat-resistant resin and a conductive layer 77b surrounding the resin ball 77a.

In the structure of the aforementioned patent publication, the external output terminal 71 is directly formed above the electrode pad 71 (flip connection). Therefore, a protective layer corresponding to the first organic insulating layer 57 or the second organic insulating layer 61 of the wafer-level CSP of FIG. 4 is not provided. Since there is not a protective layer on the package surface, the structure is susceptible to damages during package fabrication or assembly processes, and thus, defects may occur. Therefore, care needs to be taken when handling the device.

Further, according to the structure of the aforementioned Patent Publication, to attain higher reliability, a bump is formed on the electrode pad 71 directly or via the conductive material layer of the same size as the electrode pad 71, using the conductive resin ball 77.

The structure of the aforementioned Patent Publication, however, does not sufficiently protect the substrate or semiconductor elements formed in the substrate. This may cause the substrate and the like to suffer damages due to stress generated during mounting on a printed board or the like.

### SUMMARY OF THE INVENTION

The present invention has been made in view of the above circumstances and it provides a semiconductor device that can reduce damages that occur to a semiconductor substrate and the like during mounting of the device on a printed board or the like and in a use environment after the device is mounted.

An aspect of the present invention provides a semiconductor device comprising: a semiconductor substrate having a semiconductor element; an electrode pad electrically connected to the semiconductor element; an insulating layer formed on the substrate, the insulating layer having an opening extended to the electrode pad; a wiring portion electrically connected to the electrode pad via the opening, the wiring portion having an edge located on the insulating layer; and a conductive bump formed directly above the electrode pad so as to cover upper and side surfaces of the wiring portion.

According to the present invention, the edge of the wiring portion is located on the insulating layer so that stress from the conductive bump is not directly transmitted to the substrate. This reduces damages to the substrate. Thus, even though the conductive bump is formed directly above the electrode pad, cracking and the like of the substrate are suppressed.

### BRIEF DESCRIPTION OF THE DRAWINGS

The present invention will become more fully understood from the detailed description given hereinbelow and the accompanying drawings which are given by way of illustration only, and thus are not limitative of the present invention and wherein:

FIG. 1 is a cross-sectional view of the structure of a semiconductor device according to an embodiment of the present invention;

FIG. 2A to FIG. 2C are cross-sectional views illustrating fabrication steps of the semiconductor device, according to an embodiment of the present invention;

FIG. 3 is a plan view of the structure of a semiconductor device, whose electrode pads are arranged in an array form, according to an embodiment of the present invention;

FIG. 4 is a cross-sectional view of a conventional wafer-level CSP; and

FIG. 5 is a cross-sectional view illustrating a conventional mounting technique using a conductive resin ball.

### DESCRIPTION OF THE PREFERRED EMBODIMENTS

A semiconductor device of the present invention comprises: a semiconductor substrate having a semiconductor element; an electrode pad electrically connected to the semiconductor element; an insulating layer formed on the substrate, the insulating layer having an opening extended to the electrode pad; a wiring portion electrically connected to the electrode pad via the opening, the wiring portion having an edge located on the insulating layer; and a conductive bump formed directly above the electrode pad so as to cover upper and side surfaces of the wiring portion.

According to the invention, the edge of the wiring portion is located on the insulating layer so that stress from the conductive bump is not directly transmitted to the substrate. This reduces damages to the substrate. Thus, even though the conductive bump is formed directly above the electrode pad, cracking and the like of the substrate are suppressed. The phrase “directly above” means that orthogonal projections in a direction perpendicular to the substrate at least partially superimpose each other.

Since the conductive bump is formed so as to cover the upper and side surfaces of the wiring portion, there is no need to additionally provide a protective layer for protecting the wiring portion. This allows for reduction in cost. The phrase “cover a side surface” includes partial coverage of the side surface.

Hereinbelow, respective components will be described in further detail.

1. Semiconductor Substrate, Electrode Pad

The type of the semiconductor substrate is not limited, and examples of the substrate include Si substrates, GaAs substrates and the like. The type of the semiconductor element formed in the substrate is not limited, and examples of the element include transistors and diodes.

As to the electrode pad, the forming method, shape, thickness, composition and constitution (whether the pad is a single layer or a multilayer) are not limited as long as the pad can display its function.

2. Insulating Layer

The type of the insulating layer is not limited, and the insulating layer may be organic, inorganic or a laminate of organic and inorganic insulating layers (either one of the organic and inorganic insulating layers may be disposed closer to the substrate). In any case, the insulating layer serves as a protective layer. Yet, the insulating layer desirably diffuses stress and prevents cracking. It is also desirable that the insulating layer electrically isolates the wiring portion and the substrate as much as possible. Preferably, an organic insulating layer that can be easily formed as an insulating film having a thickness of several μm to several tens μm is used. As to the insulating layer, the forming method, thickness, composition and constitution are not limited as long as the layer can display its function.

As to the opening of the insulating layer, the forming method, shape and size are not limited as long as the pad is exposed.

3. Wiring Portion

As to the wiring portion, the forming method, shape, composition and constitution are not limited as long as the wiring portion is electrically connected to the pad via the opening of the insulating layer and has an edge located on the insulating layer. The thickness of the wiring portion is not limited as long as the electric connection between the pad and the bump is secured. The wiring portion may cover the opening of the insulating layer. The wiring portion may cover the opening of the insulating layer.

The wiring portion is preferably smaller than or substantially equal to the conductive bump in size of the orthogonal projection in the direction perpendicular to the substrate. With such a configuration, the conductive bump entirely covers the wiring portion and thereby is capable of protecting the whole of the wiring portion.

The wiring portion preferably includes a barrier layer and a main conductor layer. As to the main conductor layer, the forming method, shape, composition and constitution are not limited as long as the main conductor layer is conductive. The thickness of the main conductor layer is not limited as long as the electric connection between the electrode pad and the conductive bump is secured. The barrier layer has a function of preventing interdiffusion of the electrode pad and the main conductor layer. As to the barrier layer, the forming method, shape, thickness, composition and constitution are not limited as long as the barrier layer displays its function. By including the barrier layer between the main conductor layer and the insulating layer, atoms that constitute the main conductor layer can be prevented from being diffused into the insulating layer.

4. Conductive Bump

As to the conductive bump, the forming method, shape, composition and constitution are not limited as long as the bump is formed so as to cover the upper and side surfaces of the wiring portion.

The bump preferably includes a core made of a low elasticity material and a conductive layer covering the core. Such a bump can absorb stress that is caused at the time of mounting on a printed board or the like, and allows for further reduction of damages to the substrate.

The low elasticity material refers to a material with a smaller elastic modulus than a material forming the conductive layer. The low elasticity material is made of, for example, a resin with a smaller elastic modulus than the conductive layer material. As to the core, the forming method, shape, composition and constitution are not limited as long as the core is made of the low elasticity material.

As to the conductive layer, the forming method, thickness, composition and constitution are not limited as long as the conductive layer covers the core and is conductive. The conductive layer preferably includes a solder layer. The conductive layer may include a plurality of metal layers, and preferably the outermost layer thereof is a solder layer. The conductive layer, for example, includes a structure having a copper layer and a solder layer, in this order, from the inside. Where the bump includes the solder layer, a solder of the solder layer melts and covers the upper and side surfaces of the wiring portion.

By using such a bump having the low elastic core, stress that is generated in an environment where the device is mounted on a mount board and used as a product can be reduced. Thus, stress exerted on the electrode pad can be reduced even when the bump is disposed substantially directly above the pad. This suppresses cracking of the pad. In the case that the outermost layer is a solder layer, the conductive bump can be formed on the wiring portion by disposing a spherical body having the low elastic core and the solder outermost layer at a predetermined position on the wiring portion and then melting the solder layer by reflowing. Thus, the conductive bump can be produced in an inexpensive manner similar to that of a conventional bump made of a solder. The core is preferably made of a material having high heat resistance because the core is also subjected to a high temperature when the conductive layer is melt.

5. Electrode Pads Arranged in Array Form

The present invention also provides a semiconductor device comprising: a semiconductor substrate having a plurality of semiconductor elements; a plurality of electrode pads arranged in an array form, the electrode pads being electrically connected to the semiconductor elements, respectively; an insulating layer formed on the substrate, the insulating layer having a plurality of openings extended to the electrode pads, respectively; a plurality of wiring portions electrically connected to the electrode pads via the openings, respectively, and each having an edge located on the insulating layer; and a plurality of conductive bumps formed directly above the electrode pads, respectively, so as to cover upper and side surfaces of each wiring portion.

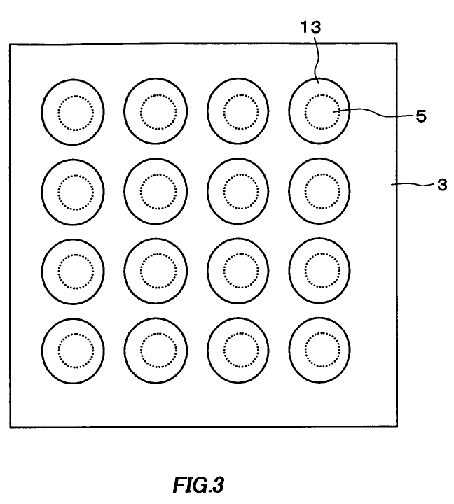

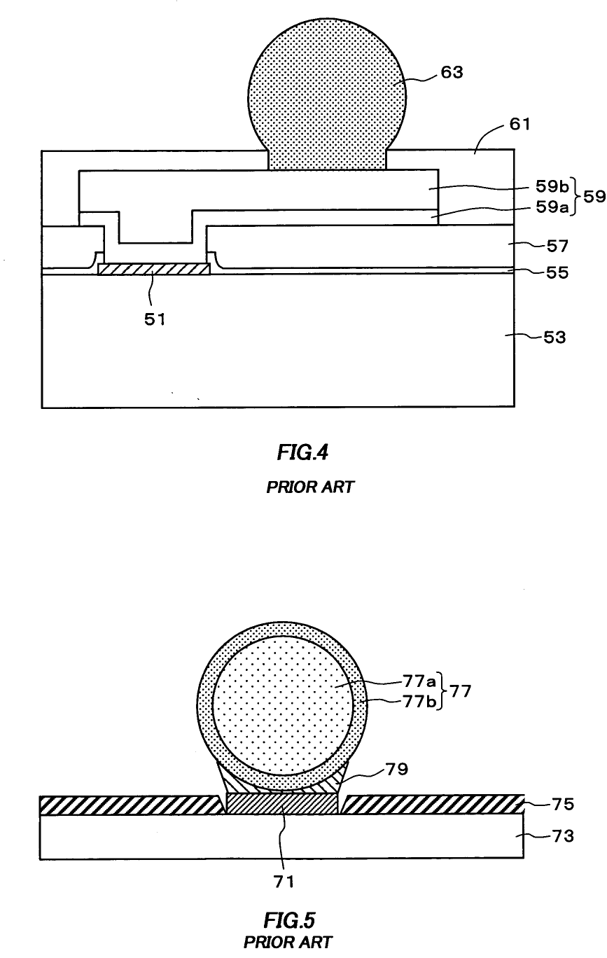

In general, electrode pads of (IC) substrates are arranged on the perimeter of the substrates, and conductive bumps of (wafer-level) CSPs are arranged in an array form on the substrates. Due to the aforementioned problem of cracking, the conductive bumps are not located directly above electrode pads, making it necessary to provide wiring portions for connecting the bumps and the pads. However, by employing the constitution of the present invention while using a substrate on which the electrode pads are arranged in an array form, all of the conductive bumps can be formed directly above the pads only. The phrase “array form” refers to a state in which a plurality of electrode pads are orderly arranged and the phrase is not limited to an arrangement of FIG. 3 in which a plurality of electrode pads are arranged on intersections of an orthogonal lattice.

With such a configuration, the distance between the electrode pads and the conductive bumps can be minimized.

This allows for minimization of parasitic capacitance/inductance generated by the wiring portion, and thereby the signal speed can be enhanced.

6. More Concrete Description Using Drawings

6-1. Structure of Semiconductor Device

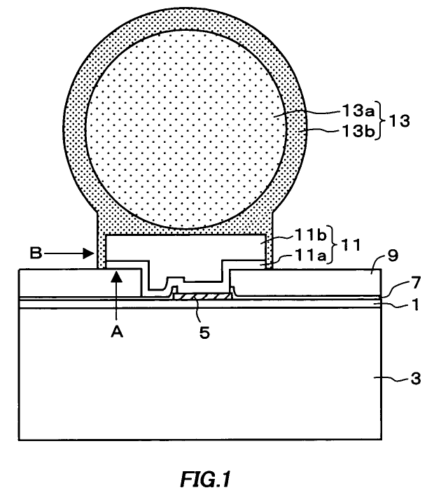

With reference to FIG. 1 (a cross-sectional view), a semiconductor device according to an embodiment of the present invention will be described. However, it should be understood that the shapes, structures, thicknesses, compositions, methods and the like described hereinbelow and in the drawings are given for the purpose of illustration, and the scope of the invention is not limited to those.

The semiconductor device of the embodiment has an electrode pad 5, which is made of a metal such as Al, Cu, AlCu, AlSi or the like, formed on a semiconductor substrate 3 including an element layer 1 in which a semiconductor element such as a transistor or the like is formed. The pad 5 is electrically connected to the semiconductor element in the element layer 1. On the substrate 3, there is formed an inorganic insulating layer 7 which is made of SiN or the like and has an opening extended to the pad 5. On the inorganic insulating layer 7, an organic insulating layer 9, which is made of polyimide, polybenzoxazole or the like and has an opening extended to the pad 5, is formed in a thickness of 3 μm to 50 μm. Further, the device includes a wiring portion 11 and a conductive bump 13 formed on the wiring portion 11. The wiring portion 11 is electrically connected to the pad 5 via the opening of the organic insulating layer 9 and has an edge A located on the organic insulating layer 9.

The wiring portion 11 is composed of a barrier layer 11a made of Ti, TiW, Cr or the like, and a main conductor layer 11b made of Cu or the like. The barrier layer 11a has a thickness of 50 Å to 2000 Å and is provided for preventing interdiffusion of the electrode pad 5 and the main conductor layer 11b and for increasing the adherence between the organic insulating layer 9 and the main conductor layer 11b. The main conductor layer 11b has a thickness of about 3 μm to 50 μm for securing connection between the bump 13 as an external output terminal and the pad 5. On an upper surface of the main conductor layer 11b, there may be formed, though not illustrated in FIG. 1, a Ni layer having a thickness of 3 μm to 10 μm for prevention of diffusion of a solder of the bump 13 and Cu of the main conductor layer 11b, and an Au layer having a thickness of 0.01 μm to 0.3 μm for improvement of wettability when mounting the bump 13.

The conductive bump 13 is composed of a core 13a made of a cross-linked divinylbenzene copolymer or the like, and a conductive layer 13b made of a copper layer and a solder layer. The solder layer is an outermost layer of the bump. The bump 13 can be formed using Micropearl SOL® manufactured by Sekisui Chemical Co., Ltd. The conductive layer 13b covers a side surface of the wiring portion as indicated by an arrow B in FIG. 1.

According to the semiconductor device of the invention, the conductive bump 13 is formed above the electrode pad 5 via the wiring portion 11 instead of being formed directly on the pad 5. The edge A of the wiring portion 11 is always located on the organic insulating layer 9. In general, where the semiconductor device is mounted on a printed board via the bump 13, stress caused by a difference in thermal expansion coefficient or the like is intensively transmitted from the bump 13 to the edge A of the wiring portion 11. Since the edge A is always located on the organic insulating layer 9 as described above, stress is not transmitted directly to the pad 5 or the element layer 1, and thus, damages thereto can be reduced.

Further, according to the semiconductor device of the invention, the bump 13 is composed of the core 13a made of a resin or the like and the conductive layer 13b covering the core 13a. The stress described above may cause cracks or the like in an interface between the bump 13 and the wiring portion 11 or between the wiring portion 11 and the organic insulating layer 9, or in the pad 5 or the element layer 1 therebelow. However, according to the present invention, the stress is lessened by the core 13a.

According to the semiconductor device of the invention, the conductive layer 13b covers the side surface of the wiring portion (indicated by the arrow B). Thus, there is no need to provide an additional insulating layer for the protection of the wiring portion 11, thereby allowing for low-cost fabrication of the device.

6-2. Fabrication Method of the Semiconductor Device

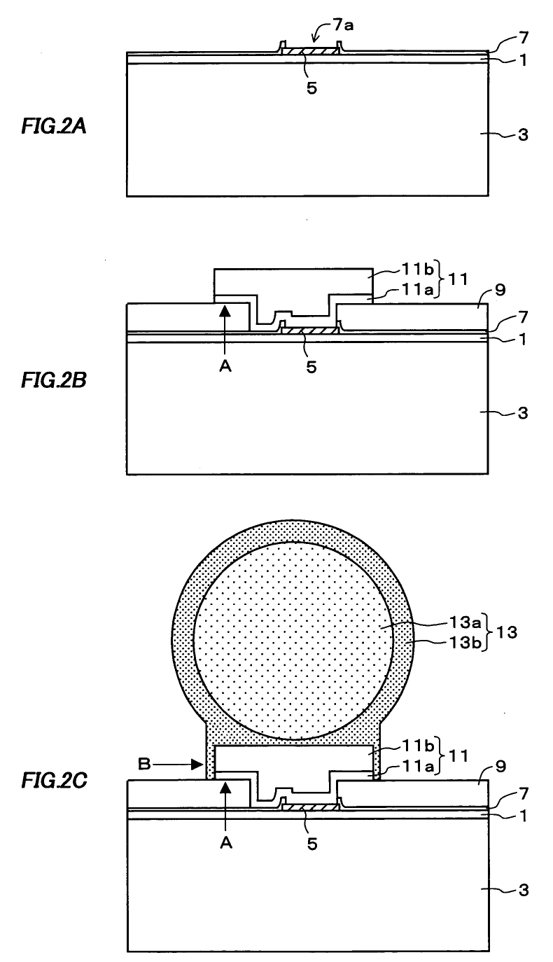

Now, referring to FIG. 2A to FIG. 2C (cross-sectional views), a fabrication method of the semiconductor device of the embodiment is explained. The under-mentioned inorganic, organic and metal layers may be formed by various known methods such as CVD, sputtering and spin-coating methods. Formation of the openings and patterning may be performed by using photolithography and etching techniques or the like.

First, the inorganic insulating layer 7 is formed on the entire surface of the semiconductor substrate 3 including the electrode pad 5 that is electrically connected to a transistor or the like in the element layer 1. Then, an opening 7a is formed in the inorganic insulating layer 7 so as to expose the electrode pad 5. Thus, a structure shown in FIG. 2A is obtained.

The organic insulating layer 9 is formed on the entire surface of the resulting substrate, and the opening is formed in the organic insulating layer 9 so as to expose the electrode pad 5. Subsequently, the barrier layer 11a and a seed layer for electrolytic plating are formed on the entire surface of the resulting substrate, and a resist layer (not shown) is formed on an area of the seed layer where a plating layer is not to be formed. Under such conditions, the electrolytic plating is performed to form the plating layer. The seed layer and the plating layer are combined into one and become the main conductor layer 11b. The barrier layer 11a and the main conductor layer 11b constitute the wiring portion 11 for electrically connecting the electrode pad 5 and the under-mentioned conductive bump 13. The resist layer is removed, and then unnecessary portions of the barrier layer and seed layer are removed. Thus, a structure shown in FIG. 2B is obtained.

Next, the conductive bump 13 including the core 13a and the conductive layer 13b having the solder layer as its outermost layer is formed on the wiring portion 11 so that a structure shown in FIG. 2C is obtained. The bump 13 is mounted by melting the outermost solder layer. In doing so, the melt solder flows down the wiring portion along its side surface, and covers and protects the wiring portion side surface as indicated by the arrow B.

The fabrication of the semiconductor device of the embodiment is thus completed with the above steps.

According to the embodiment, only one electrode pad is illustrated. However, as shown in FIG. 3 (a plan view), a plurality of electrode pads 5 may be formed in an array form on the substrate 3, and an organic insulating layer having a plurality of openings extended to the electrode pads, respectively, a plurality of wiring portions electrically connected to the electrode pads, respectively, and a plurality of conductive bumps 13 on the wiring portions, respectively, may be formed.

In such a case, the distance between the electrode pads 5 and the bumps 13, respectively, is reduced, and thereby the distance of the wiring portions connecting the two is reduced. This reduces the parasitic capacitance and the like.

The invention thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device comprising:
a semiconductor substrate having a semiconductor element;
an electrode pad electrically connected to the semiconductor element;
an insulating layer formed on the substrate, the insulating layer having an opening extended to the electrode pad;
a wiring portion electrically connected to the electrode pad via the opening, the wiring portion having an edge located on the insulating layer; and
a conductive bump formed directly above the electrode pad so as to cover upper and side surfaces of the wiring portion.

2. A semiconductor device comprising:
a semiconductor substrate having a plurality of semiconductor elements;
a plurality of electrode pads arranged in an array form, the electrode pads being electrically connected to the semiconductor elements, respectively;
an insulating layer formed on the substrate, the insulating layer having a plurality of openings extended to the electrode pads, respectively;
a plurality of wiring portions electrically connected to the electrode pads via the openings, respectively, and each having an edge located on the insulating layer; and
a plurality of conductive bumps formed directly above the electrode pads, respectively, so as to cover upper and side surfaces of each wiring portion.

3. The device of claim 1, wherein the conductive bump includes a core made of a low elasticity material and a conductive layer covering the core.

4. The device of claim 3, wherein the low elasticity material is made of a resin.

5. The device of claim 3, wherein the conductive layer includes a plurality of metal layers.

6. The device of claim 3, wherein the conductive layer includes a solder layer.

7. The device of claim 6, wherein a solder of the solder layer covers the upper and side surfaces of the wiring portion.

8. The device of claim 2, wherein the conductive bumps each include a core made of a low elasticity material and a conductive layer covering the core.

9. The device of claim 8, wherein the low elasticity material is made of a resin.

10. The device of claim 8, wherein the conductive layer includes a plurality of metal layers.

11. The device of claim 8, wherein the conductive layer includes a solder layer.

12. The device of claim 11, wherein a solder of the solder layer covers the upper and side surfaces of each wiring portion.

13. The device of claim 1, wherein the wiring portion includes a barrier layer and a main conductor layer.

14. The device of claim 2, wherein the wiring portions each include a barrier layer and a main conductor layer.
